(19) United States
(12) Patent Application Publication
(10) Pub. No.: US 2019/0330731 A1
(43) Pub. Date: Oct. 31, 2019

(54) SHEEN PRODUCT

(71) Applicant: TOYODA GOSEI CO., LTD., Kiyosu-shi (JP)

(72) Inventors: Hiroaki ANDO, Kiyosu-shi (JP); Yukari ITO, Kiyosu-shi (JP); Shintaro OKAWA, Kiyosu-shi (JP)

(21) Appl. No.: 16/390,596

(22) Filed: Apr. 22, 2019

(30) Foreign Application Priority Data
Apr. 25, 2018 (JP) 2018-084077

(51) Int. Cl. C23C 14/08; C23C 14/18; C23C 14/34

(52) U.S. Cl. CPC C23C 14/08; H01P 1/00; C23C 14/34; C23C 14/18

(57) ABSTRACT

The present invention relates to a sheen product including a base material and a metal film provided on the base material, in which the metal film includes: a first layer formed of a compound represented by a general formula Si_{X}M_{Y}O_{Z} (M represents a metal element, X>0, Y>0, Z≥0, and X+Y+Z=100); a second layer formed of In: and a third layer formed of a compound represented by a general formula Si_{X′}M′_{Y′}O_{Z′} (M′ represents a metal element, X′>0, Y′>0, Z′≥0, and X′+Y′+Z′=100), and the metal film are obtained by sputtering the first layer, the second layer and the third layer in this order.

### TECHNICAL FIELD

The present invention relates to a sheen product capable of transmitting an electromagnetic wave such as a millimeter wave.

### BACKGROUND

In order to warn a driver that an automobile is approaching a surrounding object, a millimeter wave radar apparatus for distance measurement is provided behind various parts of the automobile, such as a radiator grille, side molding, back panel, and emblem portion, in some cases. Meanwhile, it is also required for the radiator grille and the like to have a sheen property, in some cases. However, in the case where a simple metal film is provided on the radiator grille and the like for imparting a sheen property, there is a risk that the millimeter wave is blocked or largely attenuated by the metal film.

Accordingly, it is considered that a sheen product including a metal film for ensuring the sheen property and having a property of capable of transmitting a millimeter wave in the metal film is installed on a path of the millimeter wave. In order to make the metal film have the property of capable of transmitting a millimeter wave, it is necessary for the metal film to have a discontinuous structure, that is, a structure in which the metal film is not continuous on one surface and a large number of fine metal films are spread over the surface.

Conventionally, it has been considered that the metal film is formed by vacuum vapor deposition using In that has a property of easily forming a discontinuous structure by the vacuum vapor deposition. However, since In is an expensive element, in the case of using In only, production cost may increase. Furthermore, in addition to the vacuum vapor deposition, sputtering is known as a method for forming the metal film, and the sputtering is more advantageous than the vacuum vapor deposition, in view of a film thickness control and an adhesive force of the metal film.

Accordingly, a technique of forming the metal film by the sputtering while reducing the amount of In usage by using a material other than In, has been proposed. As such a technique, a technique of sequentially forming a metal film formed of Al, a metal film formed of In, and a metal film formed of Al on a base material formed of resin by using the sputtering has been known (refer to, e.g., Patent Document 1).

Patent Document 1: Japanese Patent No. 4732147

### SUMMARY

Although the sheen product (referred to as “Al—In—Al product”) obtained by the above-described method has sufficiently good performance in terms of capability of transmitting a millimeter wave and the like, when the Al—In—Al product is produced, Al which is relatively easy to oxidize becomes a target of the sputtering. Accordingly, it is necessary to perform cleaning (e.g., pre-etching using plasma, etc.) for removing oxides from the Al target at a relatively high frequency before product is produced or the like, and thus, there is room for improving productivity. Therefore, in order to improve the productivity, it is desirable to newly produce a sheen product having as good capability of transmitting a millimeter wave and the like as that of the Al—In—Al product, by using a target which is relatively difficult to oxidize, other than Al.

The present invention was made in view of the above-described circumstances, and an object of the present invention is to provide a sheen product that can sufficiently transmit a millimeter wave and can improve productivity.

Hereinafter, respective aspects of the present invention, suitable for solving the above-described object will be described. An action effect peculiar to the corresponding aspect will be described as necessary, too.

A first aspect of the present invention is a sheen product including a base material and a metal film provided on the base material,

in which the metal film includes: a first layer formed of a compound represented by a general formula Si_{X}M_{Y}O_{Z} (here, M represents a metal element, and X, Y and Z represent numerical values satisfying X>0, Y>0, Z≥0, and X+Y+Z=100); a second layer formed of In: and a third layer formed of a compound represented by a general formula Si_{X′}M′_{Y′}O_{Z′} (here, M′ represents a metal element, and X′, Y′ and Z′ represent numerical values satisfying X′>0, Y′>0, Z′≥0, and X′+Y′+Z′=100), and

the metal film are obtained by sputtering the first layer, the second layer and the third layer in this order.

According to the first aspect of the present invention, the first layer and the third layer can be obtained by sputtering with a target including at least Si and M. Here, since Si has a property that is hard to be oxidized as compared with Al., a frequency of cleaning the target can be reduced. As a result, productivity can be improved.

When O₂ is supplied into a chamber of a sputtering apparatus during formation of the first layer and the third layer and O₂ reactive sputtering is performed, the first layer and the third layer can be made to contain oxygen (O) together with Si and M constituting a target material. In addition, when only an inert gas such as Ar is supplied into the chamber, the first layer or the third layer can be made not to contain the oxygen (O) (i.e., Z=Z′=0 can be satisfied). Of course, a ratio (e.g., mass ratio) of elements constituting the first layer may be different from that of elements constituting the third layer (i.e., X≠X′, Y≠Y′ and/or Z≠Z′ may be satisfied).

In addition, according to the first aspect of the present invention, a millimeter wave can be transmitted sufficiently. This is because particles constituting the first layer serve as growth nuclei, from which In constituting the second layer can be grown as independent island shape spaced apart from each other or only partially contacted with each other. That is, this is because a well reliable formation of a discontinuous structure is achieved. In addition, the third layer functions as a protective film. Since the third layer is formed to maintain the island-shape growth on In grown in the island shape, the third layer hardly affects adversely in terms of the capability of transmitting a millimeter wave.

A second aspect of the present invention is the sheen product described in the first aspect, in which the M and the M′ are each independently at least one element selected from the group consisting of Sn and Zr.

According to the second aspect of the present invention, an Si—Sn alloy and/or an Si—Zr alloy can be used as a target of sputtering. The use of these alloys as a target material can sufficiently improve a film formation speed of the first layer and/or third layer, and can more reliably improve the productivity.

Furthermore, since the target material includes Sn and/or Zr, an equipment change accompanying a change of the target can be minimized, which leads to suppression of an increase in production cost. That is, in the case where a target of sputtering is mere Si or SiO₂, Si is a semiconductor and SiO₂ is an insulator. Therefore, when sputtering is performed by using a direct current power supply, positive ions (e.g., Ar³) formed by ionizing the gas introduced into the chamber may be charged on a surface of the target and a surface potential of the target tends to increase, which may lead to a decrease in sputtering efficiency. Accordingly, in order to perform stable sputtering, it is necessary to use a high-frequency power supply or a pulse power supply to cancel the charging due to the ions. In contrast to this, according to the second aspect of the present invention, since the target contains Sn and/or Zr, the target becomes an electric conductor and the charging due to the ions is eliminated, and therefore, sputtering can be performed by using a direct current power supply. Thus, it is unnecessary to prepare the high-frequency power supply or the like, and the equipment change accompanying the change of the target can be minimized. As a result, an increase in production cost can be suppressed.

In addition, according to the second aspect of the present invention, a millimeter wave can be more reliably transmitted by using Sn and/or Zr as M.

A third aspect of the present invention is the sheen product described in the first or second aspect, in which Z′>0 is satisfied.

According to the third aspect of the present invention, corrosion resistance can be improved by forming the third layer as an oxide film.

In addition, in the case where the third layer is an oxide film, the third layer can have an excellent affinity for liquid, that is, wettability of the third layer can be improved. Thus, in the case where coating such as a suppression coating is performed on a surface of the metal film, or a film or the like is attached to the surface of the metal film via an adhesive, affinity of the metal film with respect to the coating material or the adhesive can be improved. Accordingly, adhesion of the coating material or the adhesive to the metal film can be enhanced, and the coating material or the film can be more reliably prevented from being peeled off.

### BRIEF DESCRIPTION OF DRAWINGS

FIG. 1 is an enlarged cross-sectional schematic diagram of a sheen product.

FIG. 2 is a schematic diagram based on a cross-sectional TEM image of the sheen product.

FIG. 3 is a schematic diagram of a sputtering apparatus.

FIG. 4 is a schematic diagram illustrating measurement of a contact angle.

### EMBODIMENTS

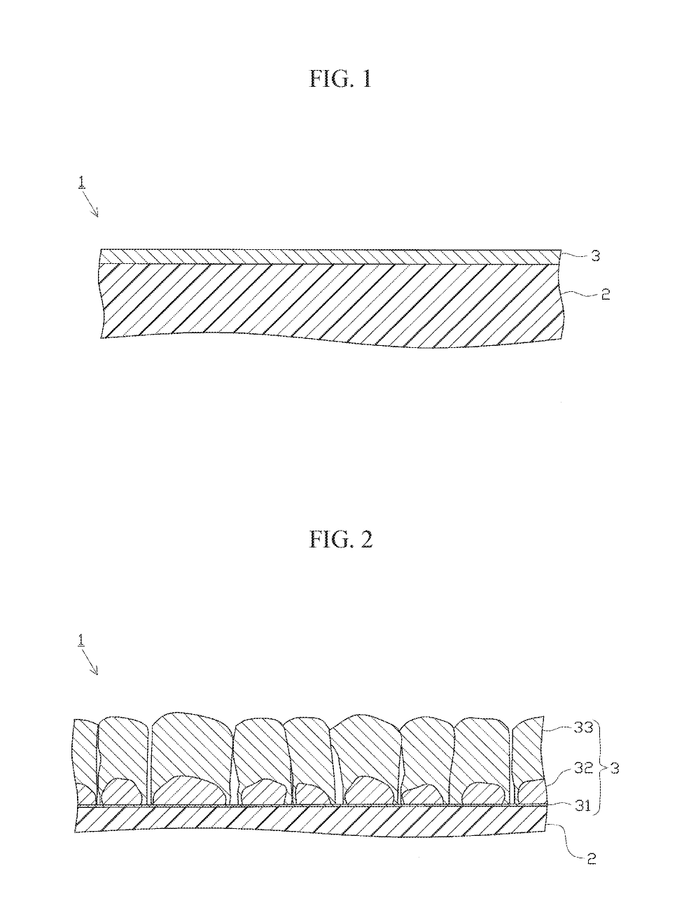

Hereinafter, one embodiment of the present invention will be described with reference to the drawings. As illustrated in FIG. 1, a sheen product 1 includes a base material 2 formed of a resin and a metal film 3 formed on a surface of the base material 2. Examples of the sheen product 1 include a cover for millimeter wave radar apparatus, and the like. Although an application target of the sheen product 1 is not limited in particular, the sheen product 1 can be applied to, for example, an externally coated product of an automobile (e.g., specifically, a radiator grille, a grille cover, a side molding, a back panel, a bumper, an emblem, etc.).

Examples of the base material 2 include a plate material, a sheet material, a film material, and the like formed of a predetermined resin. The base material 2 according to the present embodiment is formed of an acrylonitrile-ethylene-styrene copolymer (AES) resin that is a resin material having a small dielectric tangent (index value indicating a degree of loss of electric energy in the dielectric). Examples of the material constituting the base material 2 include acrylonitrile-styrene-acrylate copolymer (ASA) resins, polycarbonate (PC) resins, acrylonitrile-butadiene-styrene copolymer (ABS) resins, PC/ABS resins, acrylic resins, polystyrene (PS) resins, polyvinyl chloride (PVC) resins, polyurethane (PU) resins, polypropylene (PP) resins, and the like. Of course, the base material 2 may be formed of a material other than resins as long as the material can sufficiently transmit a millimeter wave.

In addition, a base film (to be a base of the metal film 3) may be formed on the base material 2. As the base film, use can be made of a base film formed of an organic compound [e.g., a coating film formed by applying an organic coating material (acrylic coating material, etc.)], a base film formed of an inorganic compound [e.g., a coating film formed by applying an inorganic coating material, a thin film formed of a metal compound formed by means of a physical vacuum vapor deposition method, etc.].

The metal film 3 is a thin film formed on a surface of the base material 2 and is provided to ensure a sheen property of the surface of the sheen product 1. Although not illustrated in particular in the present embodiment, the surface of the metal film 3 may be subjected to coating such as top coating or press coating, or a film may be attached via an adhesive, as necessary. In addition, the metal film 3 may be coated with a corrosion preventing layer formed of an acrylic resin material or an urethane resin material.

As illustrated in FIG. 2, the metal film 3 is a laminate in which a first layer 31, a second layer 32 and a third layer 33 are sequentially formed on the base material 2 in this order, in which each of the first layer 31, second layer 32 and third layer 33 are formed by sputtering. The metal film 3 has a discontinuous structure, has a sheen property, and can transmit a millimeter wave (e.g., an electromagnetic wave having a wavelength of from 1 mm to 10 mm and a frequency of from 30 GHz to 300 GHz) therethrough. FIG. 2 is a schematic diagram based on a cross-sectional image of the sheen product 1, which is obtained by a transmission electron microscope (TEM).

The first layer 31 is a very thin film (e.g., film formed with an aim to have a thickness of 5 nm), and is formed to be closest to the surface of the base material 2 among the first layer 31, second layer 32 and third layer 33. Particles constituting the first layer 31 mainly function as growth nuclei of the second layer 32. In FIG. 2, the first layer 31 is illustrated to be thicker than an actual ratio for emphasis. In addition, although the first layer 31 is schematically illustrated as a layer shape (film shape) in FIG. 2, FIG. 2 is a schematic diagram only, and the first layer 31 actually (finally) formed does not necessarily have such a layer shape and may be formed in a dot shape in a dispersed state on the surface of the base material 2 in some cases.

The second layer 32 includes a thick film portion formed on the particle of the first layer 31 as a growth nucleus. The third layer 33 is formed in a state of being particularly laminated with respect to the thick film portion of the second layer 32. Accordingly, the metal film 3 has a discontinuous structure, that is, a structure in which the metal film is not continuous on one surface and a large number of fine metal films are slightly spaced apart from each other in an island shape or are spread in a state where only a part thereof is in contact with each other.

The second layer 32 is formed with an aim to have a thickness of, for example, from 25 nm to 30 nm, and the third layer 33 is formed with an aim to have a thickness of, for example, from 10 nm to 130 nm. In order to more reliably prevent an adverse effect from occurring in terms of the capability of transmitting the millimeter wave, the thickness of the third layer 33 is preferably set to 130 nm or less. In addition, from the viewpoint of obtaining a sufficient sheen property, the thickness of the metal film 3 is preferably set to 10 nm or more.

The second layer 32 is formed of In. On the other hand, the first layer 31 is formed of a compound represented by a general formula Si_{X}M_{Y}O_{Z}, and the third layer 33 is formed of a compound represented by a general formula Si_{X′}M′_{Y′}O_{Z′}. M and M′ each independently represents a metal element. X, Y, and Z satisfy X>0, Y>0, Z≥0 and X+Y+Z=100. X′, Y′, and Z′ satisfy X′>0, Y′>0, Z′≥0 and X′+Y′+Z′=100.

In the present embodiment, the M is Sn or Zr. That is, in the present embodiment, the first layer 31 is formed of a compound represented by a general formula Si_{X}Sn_{Y}O_{Z} or a compound represented by a general formula Si_{X}Zr_{Y}O_{Z}. Particularly, in the present embodiment, Z=0 is satisfied, that is, the first layer 31 is a non-oxide film.

Like in the first layer 31, the third layer 33 is also formed of a compound represented by the general formula Si_{X′}Sn_{Y′}O_{Z′} or a compound represented by the general formula Si_{X′}Zr_{Y′}O_{Z′}. However, in the present embodiment, Z′>0 is satisfied, that is, the third layer 33 is formed of an oxide film. The third layer 33 functions as a protective film. Since the third layer 33 is formed to maintain island-shape growth on In (second layer 32) grown in an island shape, the third layer 33 hardly affects adversely in terms of the capability of transmitting the millimeter wave.

The metal film 3 may have a constitution where both of the first layer 31 and the third layer 33 are oxide films or are non-oxide films. In addition, the metal film 3 may have a constitution where the first layer 31 is an oxide film and the third layer 33 is a non-oxide film. The oxide film can be formed by performing an O₂ reactive sputtering as will be described below, and the non-oxide film can be formed by performing sputtering under an inert-gas atmosphere as will be described below.

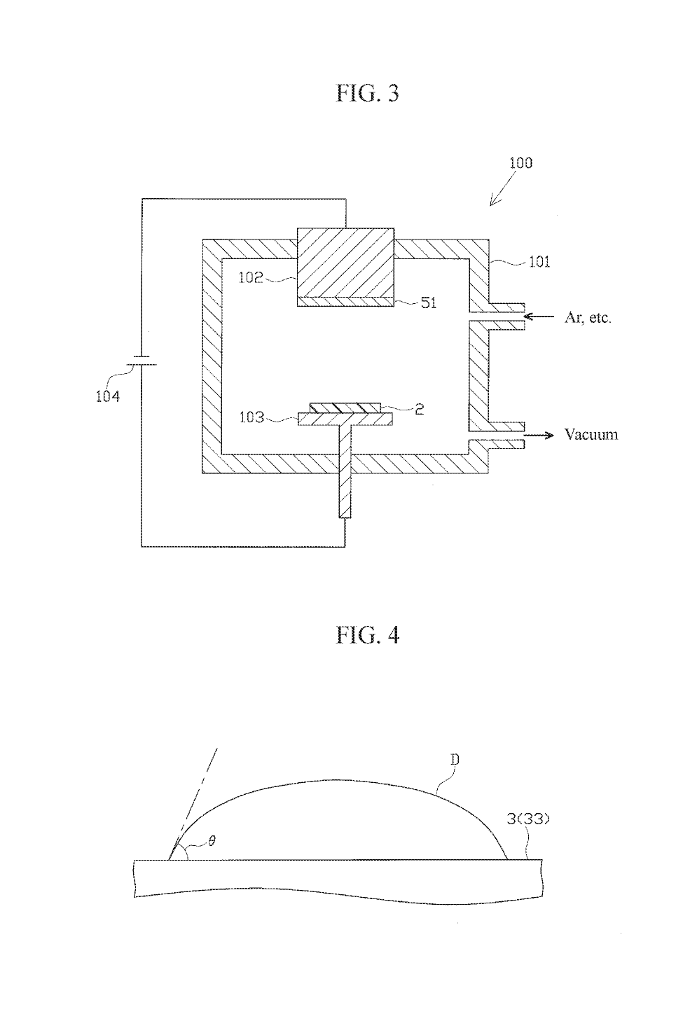

Regarding the methods for producing the sheen product 1 described above, a method for forming the metal film 3 on the base material 2 will be described below in particular. First, as necessary, a base film or the like is formed on the surface of the base material 2. After that, as illustrated in FIG. 3, a target 51 serving as a film forming material of the first layer 31 is set on a target holder 102 provided in a chamber 101 of a sputtering apparatus 100. The base material 2 is set on a base material holder 103 in the chamber 101. In the case where the first layer 31 is formed of the compound represented by the general formula Si_{X}Sn_{Y}O_{Z}, a material formed of an Sn—Si alloy (e.g., an alloy containing 50% by mass of Sn and 50% by mass of Si) is used as the target 51. In the case where the first layer 31 is formed of the compound represented by the general formula Si_{X}Zr_{Y}O_{Z}, a material formed of a Zr—Si alloy is used as the target 51.

Then, a direct current high voltage is applied between the base material 2 and the target 51 by a direct current power supply (DC power supply) 104 while introducing an inert gas (e.g., Ar gas) into the chamber 101 (i.e., under an inert-gas atmosphere). In this manner, Ar is ionized and forced to collide with the target 51, and a constituting material of the target 51 is ejected outside and deposited on the base material 2 to form the first layer 31. Since sputtering is performed in an inert-gas atmosphere, the first layer becomes a non-oxide film.

Next, a material formed of In is used as the target 51, and a direct current high voltage is applied between the base material 2 and the target 51 by the DC power supply 104 while introducing an inert gas (e.g., Ar gas) into the chamber 101 in the same manner as described above. In this manner, the constituting material (In) of the target 51 is deposited on the base material 2 to form the second layer 32 formed of In. At this time, particles constituting the first layer 31 serve as growth nuclei, from which In constituting the second layer grows in an independent island shape spaced apart from each other or only partially contacted with each other.

Furthermore, a material formed of an Sn—Si alloy or a Zr—Si alloy is used as the target 51, and a direct current high voltage is applied between the base material 2 and the target 51 while introducing an inert gas (e.g., Ar gas) and O₂ gas into the chamber 101. In this manner, a constituting material of the target 51 is forced to react with O₂ and the resultant material is deposited on the base material 2 (i.e., O₂ reactive sputtering is performed), thereby forming the third layer 33 that is an oxide film. As a result, the metal film 3 constituted by the first layer 31, the second layer 32 and the third layer 33 can be formed on the base material 2.

As described above in detail, according to the present embodiment, the first layer 31 and the third layer 33 can be obtained by sputtering using the target 51 containing at least Si and M (M is Sn or Zr in the present embodiment). Here, since Si has a property hard to be oxidized as compared with Al, the frequency of cleaning of the target 51 can be reduced. As a result, productivity can be improved.

Furthermore, the third layer 33 is formed to maintain the island-shape growth on In (second layer 32) grown in an island shape, and the discontinuous structure can be formed more reliably in the metal film 3. Therefore, the metal film 3 hardly affects adversely in terms of the capability of transmitting the millimeter wave. Accordingly, the sheen product 1 can sufficiently transmit the millimeter wave.

In addition, materials formed of an Si—Sn alloy and/or a Si—Zr alloy can be used as the target 51 of the sputtering. Use of these alloys as the material of the target 51 can sufficiently improve a film formation speed of the first layer 31 and the third layer 33, and can more reliably improve the productivity.

In addition, since the target 51 according to the present embodiment includes Sn and/or Zr, the target 51 serves as an electric conductor and charging due to ions is eliminated. Therefore, sputtering can be performed by using the DC power supply 104. As a result, an equipment change accompanying a change of the target can be minimized, and an increase in production cost can be suppressed.

Furthermore, since the third layer 33 according to the present embodiment is constituted by an oxide film, corrosion resistance can be improved.

Furthermore, since the third layer 33 according to the present embodiment is an oxide film, the third layer 33 can have an excellent affinity for liquid. That is, wettability of the third layer 33 can be improved. Thus, in the case where coating is performed on the surface of the metal film 3 or in the case where a film or the like is attached via an adhesive, conformability of the coating material or the adhesive to the metal film 3 can be improved. Therefore, adhesion of the coating material or the adhesive to the metal film 3 can be enhanced, and the coating material or the film can be more reliably prevented from being peeled off.

### EXAMPLES

Next, in order to confirm an action effect of the above-described embodiment of the present invention, samples of a plurality of types of sheen products were produced by forming a first layer, a second layer and a third layer by sputtering respectively on a base material formed of PC. Then, the amount of attenuation (dB) at the time when a millimeter wave transmits therethrough was measured for each sample. Here, it can be said that the millimeter wave is more sufficiently transmitted as the amount of attenuation is smaller. It can be said that the millimeter wave is sufficiently and favorably transmitted in the case where the amount of attenuation is 3.00 dB or less. Table 1 shows the amount of attenuation of the millimeter waves in each sample.

In forming the first layer and the third layer in each sample, a target formed of Si, an Sn—Si alloy or a Zr—Si alloy was used, and an oxide film or a non-oxide film was formed by sputtering using a direct current power supply while introducing O₂ gas into a chamber or without introducing O₂ gas. That is, a material constituted by a compound formed Si and O, a compound represented by the general formula Si_{X}Sn_{Y}O_{Z}, or a compound represented by the general formula Si_{X}Zr_{Y}O_{Z} was formed as the oxide film (here, X, Y and Z indicates numerical values satisfying X>0, Y>0, Z>0 and X+Y+Z=100). In addition, a material constituted by Si, a compound represented by a general formula Si_{X}Sn_{Y}, or a compound represented by a general formula Si_{X}Zr_{Y} was formed as the non-oxide film (here, X and Y indicate numerical values satisfying X>0, Y>0, and X+Y=100). The second layer was formed by using a target formed of In.

In addition, for each sample, the first layer was formed with an aim to have a thickness of 5 nm, the second layer was formed with an aim to have a thickness of 25 nm, and the third layer was formed with an aim to have a thickness of 15 nm.

In addition, for each sample, a surface resistance (Ω/□) of the metal film, a gloss value measured by a gloss meter under the condition of a measurement angle of 60° according to JIS Z8741 (1997), and brightness L* in the colorimetric system (L*, a*, b*) defined in the CIE 1976 colorimetric system (JIS Z8729 (2004)) measured by a color difference meter were measured, and the results are also shown in Table 1 as a reference.

TABLE 1

| Metal film | | Target type | | |
|---|---|---|---|---|
| constitution | Evaluation item | Si | Sn—Si | Zr—Si |
| Non-oxide/In/ | Amount of | 1.76 | 2.68 | 1.81 |
| non-oxide (5 nm/ | attenuation of | | | |
| 25 nm/15 nm) | millimeter wave | | | |
| | [dB] | | | |
| | Surface resistance | 2.65E+11 | 1.59E+11 | 3.99E+05 |
| | [Ω/□] | | | |
| | Gloss | 268.47 | 272.27 | 275.07 |
| | L* | 82.60 | 79.45 | 82.77 |
| Non-oxide/In/ | Amount of | 1.70 | 1.66 | 1.79 |
| oxide (5 nm/ | attenuation of | | | |
| 25 nm/15 nm) | millimeter wave | | | |
| | [dB] | | | |
| | Surface resistance | 1.62E+11 | 1.26E+11 | 1.17E+04 |
| | [Ω/□] | | | |
| | gloss | 252.67 | 264.23 | 226.10 |
| | L* | 79.53 | 81.17 | 75.14 |
| Oxide/In/ | Amount of | 1.85 | 2.01 | 1.76 |
| oxide (5 nm/ | attenuation of | | | |
| 25 nm/15 nm) | millimeter wave | | | |
| | [dB] | | | |
| | Surface resistance | 3.56E+09 | 4.36E+06 | 2.20E+08 |
| | [Ω/□] | | | |
| | gloss | 257.13 | 246.20 | 255.23 |
| | L* | 79.93 | 75.81 | 78.39 |

As shown in Table 1, it was confirmed that each sample showed amount of attenuation of the millimeter wave being 3.00 dB or less and could transmit the millimeter wave sufficiently and favorably.

In addition, it was confirmed that each sample was also satisfactory in terms of the gloss value and the brightness L* and had a sufficiently good sheen property.

Next, an O₂ reactive sputtering was performed by using an Sn—Si target or Zr—Si target formed of an Sn—Si alloy or a Zr—Si alloy (Example). An O₂ reactive sputtering was performed by using an Si target formed of Si (Comparative Example 1). A sputtering is performed by using an Al target formed of Al in an inert-gas atmosphere (Comparative Example 2). In Example and Comparative Examples 1 and 2, a film formation speed (Å/sec·W) at the time of forming the third layer was calculated. A value obtained by dividing a formation thickness (Å) of the third layer 33 by the product of a power (application power) W at the time of sputtering and a sputtering time (sec), that is, a value corresponding to the film thickness per unit time excluding affection of the power, was calculated as the film formation speed. In the case where an Sn—Si target or a Zr—Si target was used, O₂ gas was introduced into the chamber such that O₂ partial pressure was 33% during the sputtering. In the case where an Si target was used, O₂ gas was introduced into the chamber such that the O₂ partial pressure was 23% during the sputtering.

As a result of calculation, the film formation speed was approximately 0.008 Å/sec·W in the case of using the Si target and was approximately 0.007 Å/sec·W in the case of using the Al target. Whereas the film formation speed was approximately 0.032 Å/sec·W in the case of using the Sn—Si target and was approximately 0.018 Å/sec·W in the case of using the Zr—Si target. That is, it is confirmed that the film formation speed can be remarkably improved in the cases where the Sn—Si target and the Zr—Si target were used. From this result, it can be said that an Si—Sn alloy or a Si—Zr alloy is preferably used as a sputtering target from the viewpoint of forming a metal film having a desired thickness in a shorter time.

Next, samples of the sheen product were prepared each by forming an oxide film or a non-oxide film as a third layer by sputtering using a material formed of Si, an Sn—Si alloy or a Zr—Si alloy as a sputtering target while introducing O₂ gas into the chamber such that the O₂ partial pressure became 33% or without introducing O₂ gas. Wettability of each sample was evaluated. As illustrated in FIG. 4, the evaluation of the wettability was performed by dropping a droplet D (ion-exchanged water) onto an outermost surface (surface of the third layer 33) of the metal film 3 of the sample and by measuring a contact angle θ of the droplet D by a tangent method. Here, the smaller the contact angle θ is, the better the wettability is. Table 2 shows contact angles θ of the respective samples.

TABLE 2

| Third layer | Evaluation item | Si | Sn—Si | Zr—Si |
|---|---|---|---|---|
| Non-oxide | Contact angle θ [°] | 19.9 | 48.2 | 41.7 |
| Oxide | | 9.2 | 7.9 | 10.3 |

As shown in Table 2, it is clear that the sample in which the third layer is formed as an oxide film has an extremely small contact angle θ as compared with the sample in which the third layer is formed as a non-oxide film, and has extremely good wettability. From this result, it can be said that the third layer is preferably formed as an oxide film from the viewpoint of enhancing adhesion of a coating material, an adhesive and the like.

When the contact angle θ was measured also in the same manner for the conventional product in which the third layer was formed of Al, the contact angle θ was approximately 75°. Thus, even in the case where the third layer is formed as a non-oxide film, better adhesion of a coating material or the like than that of the conventional product can be obtained.

The present invention is not limited to the description of the above embodiments and can be embodied with an appropriate change or modification within a range without departing from the gist of the present invention.

The present application is based on the Japanese Patent Application No. 2018-084077 filed on Apr. 25, 2018, which contents are incorporated herein by reference.

### DESCRIPTION OF REFERENCE NUMERALS AND SIGNS

1: sheen product,
2: base material,
3: metal film,
31: first layer,
32: second layer,
33: third layer.

What is claimed is:

1. A sheen product comprising:
a base material; and
a metal film provided on the base material,
wherein the metal film comprises:
a first layer formed of a compound represented by a general formula Si_{X}M_{Y}O_{Z} (here, M represents a metal element, and X, Y and Z represent numerical values satisfying X>0, Y>0, Z≥0, and X+Y+Z=100);
a second layer formed of In; and
a third layer formed of a compound represented by a general formula Si_{X′}M′_{Y′}O_{Z′} (here, M′ represents a metal element, and X′, Y′ and Z′ represent numerical values satisfying X′>0, Y′>0, Z′≥0, and X′+Y′+Z′=100), and
wherein the metal film are obtained by sputtering the first layer, the second layer and the third layer in this order.

2. The sheen product according to claim 1,
wherein the M and the M′ are each independently at least one element selected from the group consisting of Sn and Zr.

3. The sheen product according to claim 1,
wherein Z′>0 is satisfied.

4. The sheen product according to claim 2,
wherein Z′>0 is satisfied.

5. A method for producing sheen product, comprising steps of:
sputtering a first layer formed of a compound represented by a general formula Si_{X}M_{Y}O_{Z} on or above a surface of (here, M represents a metal element, and X, Y and Z represent numerical values satisfying X>0, Y>0, Z≥0, and X+Y+Z=100):
sputtering a second layer formed of In on or above the first layer; and
sputtering a third layer formed of a compound represented by a general formula Si_{X′}M′_{Y′}O_{Z′} (here, M′ represents a metal element, and X′, Y′ and Z′ represent numerical values satisfying X′>0, Y′>0, Z′≥0, and X′+Y′+Z′=100) on or above the second layer.

6. The method according to claim 5,
wherein the M and the M′ are each independently at least one element selected from the group consisting of Sn and Zr.

7. The method according to claim 5,
wherein Z′>0 is satisfied.

8. The method according to claim 6,
wherein Z′>0 is satisfied.
